(19) United States
(12) Patent Application Publication
(10) Pub. No.: US 2019/0146007 A1
(43) Pub. Date: May 16, 2019

(54) SHUNT RESISTOR AND METHOD OF MOUNTING THE SAME

(71) Applicant: DENSO CORPORATION, Kariya-city (JP)

(72) Inventors: Junpei TAKAISHI, Kariya-city (JP); Hiromasa HAYASHI, Kariya-city (JP)

(21) Appl. No.: 16/245,611

(22) Filed: Jan. 11, 2019

Related U.S. Application Data
(63) Continuation of application No. PCT/JP2017/026176, filed on Jul. 20, 2017.

(30) Foreign Application Priority Data
Jul. 21, 2016 (JP) 2016-143302

(51) Int. Cl. G01R 15/14; H01C 1/04; H01C 1/142; H01C 13/02; G01R 1/20; G01R 19/10

(52) U.S. Cl. CPC G01R 15/146; H01C 1/04; G01R 19/10; H01C 13/02; G01R 1/203; H01C 1/142

(57) ABSTRACT

A shunt resistor has a resistance element with a predetermined resistivity at least at a part, and the shunt resistor to which a bonding wire is to be connected. The bonding wire is for detecting a value of current flowing between two electrodes bridged through the shunt resistor by detecting a voltage drop at the resistance element. The shunt resistor includes: a pair of connection parts to be respectively electrically connected to the two electrodes; a bridge part having the resistance element, extending from one of the connection parts to the other of the connection parts, and bridging the pair of connection parts; and a mark configured to define a virtual line segment. The mark is arranged to allow the virtual line segment to be oblique with respect to an extending direction of the bridge part.

### CROSS REFERENCE TO RELATED APPLICATIONS

The present application is a continuation application of International Patent Application No. PCT/JP2017/026176 filed on Jul. 20, 2017, which designated the U.S. and claims the benefit of priority from Japanese Patent Application No. 2016-143302 filed on Jul. 21, 2016. The entire disclosures of all of the above applications are incorporated herein by reference.

### TECHNICAL FIELD

The present disclosure relates to a shunt resistor and a method of mounting the shunt resistor.

### BACKGROUND

The measurement of a current value with the use of a shunt resistor is based on a resistance value of the resistance element in the shunt resistor and a voltage across both ends of the shunt resistor. A bonding wire for obtaining the voltage is bonded with metal strips, which are joined together with a resistance element such that the metal strips are opposite to each other with respect to the resistance element. It is preferable that the bonding position of the bonding wire is arranged closer to the resistance element on the metal strip, because an electrical resistance caused by the metal strips may be superimposed as noise of the current to be detected. In addition, an inductive current may be generated at a current path including the bonding wire because of a current flowing through the shunt resistor.

### SUMMARY

The present disclosure provides a shunt resistor including a mark to define a virtual line segment when a surface of the shunt resistor to which a bonding wire is to be connected is imaged from a front view.

### BRIEF DESCRIPTION OF DRAWINGS

The above object, the other objects, features, and advantages of the present disclosure will become more apparent from the following detailed description with reference to the accompanying drawings, in which:

FIG. 1 is a perspective view showing a schematic configuration of a shunt resistor according to a first embodiment;

FIG. 2 illustrates a formation position and a shape of a mark at the shunt resistor;

FIG. 3 is a top view illustrating bonding coordinates in a situation when a shift of the shunt resistor does not occur in the rotational direction;

FIG. 4 is a top view illustrating bonding coordinates in a situation when a shift of the shunt resistor occurs in the rotational direction;

FIG. 5 illustrates a formation position and a shape of a mark according to a second embodiment; and

FIG. 6 illustrates the formation position and the shape of the mark according to the second embodiment.

### DETAILED DESCRIPTION

Higher bonding accuracy is required for the shunt resistor. In a method of mounting a shunt resistor as a comparative example, an origin is determined based on an edge detected when the shunt resistor is imaged in a direction orthogonal to a surface of the shunt resistor to which a bonding wire is to be bonded. When the shunt resistor is placed along an X-direction, two coordinates separated by a predetermined distance from the determined origin are determined as the bonding position. As a result, it is possible to correct the bonding position with respect to a shift in a translational direction of the shunt resistor.

In such a method, it is based on an assumption of the shunt resistor's longitudinal direction being along one direction (for example, X-direction) defined by a coordinate system included in the imaging device. In other words, in a situation where the shunt resistor's longitudinal direction is along the X-direction, it may be possible to correct the position with respect to the shift in the translational direction. However, it may not be adequate to deal with a situation when the shunt resistor is shifted in the rotational direction. The shift in the rotational direction may cause a bonding fault, in particular, the bonding wire bonded to the resistor itself.

According to an aspect of the present disclosure, a shunt resistor has a resistance element with a predetermined resistivity at least at a part, and to which a bonding wire is to be connected. The bonding wire is used for detecting a value of current flowing between two electrodes bridged through the shunt resistor by detecting a voltage drop at the resistance element. The shunt resistor includes a pair of connection parts, a bridge part and a mark. The pair of connection parts is to be respectively electrically connected to the two electrodes. The bridge part has the resistance element, and extends from one of the connection parts to the other of the connection parts, and bridges the pair of connection parts. The mark is configured to define a virtual line segment when a surface of the shunt resistor, which is to be connected with the bonding wire, is imaged from a front view. The mark is arranged to allow the virtual line segment to be oblique with respect to an extending direction of the bridge part.

Accordingly, the virtual line segment can be defined by detecting the mark from the image data of the shunt resistor, which is imaged. The angular difference θ can be detected between the virtual line segment at the shunt resistor and a preliminarily defined straight line. It is possible to correct the shift of the connection position of the bonding wire in the rotational direction according to the angular difference θ.

Embodiments of the present disclosure will be hereinafter described with reference to the drawings. Parts identical or equivalent to each other among various drawings are given the same reference numerals.

In the following description, a local coordinate system and a global coordinate system are used. The local coordinate system is fixed at a shunt resistor. The global coordinate system is fixed at an imaging device for taking an image of the shunt resistor to calculate the connection position of a bonding wire.

With regard to the global coordinate system, an x-direction, a y-direction orthogonal to the x-direction, and a z-direction, which is orthogonal to the xy plane defined by the x and y-directions, are defined as the directions. In other words, the x-direction, y-direction and z-direction are linearly independent to each other.

With regard to the local coordinate system, a u-direction, a v-direction orthogonal to the u-direction, and a w-direction which is orthogonal to an uv-plane defined by the u-direction and v-direction are defined as the directions. In other words, the u-direction, v-direction and w-direction are linearly independent to each other.

It is rare that the z-direction and w-direction are significantly different in the mounting of the shunt resistor. The z-direction is parallel to the w-direction as described in the following.

### First Embodiment

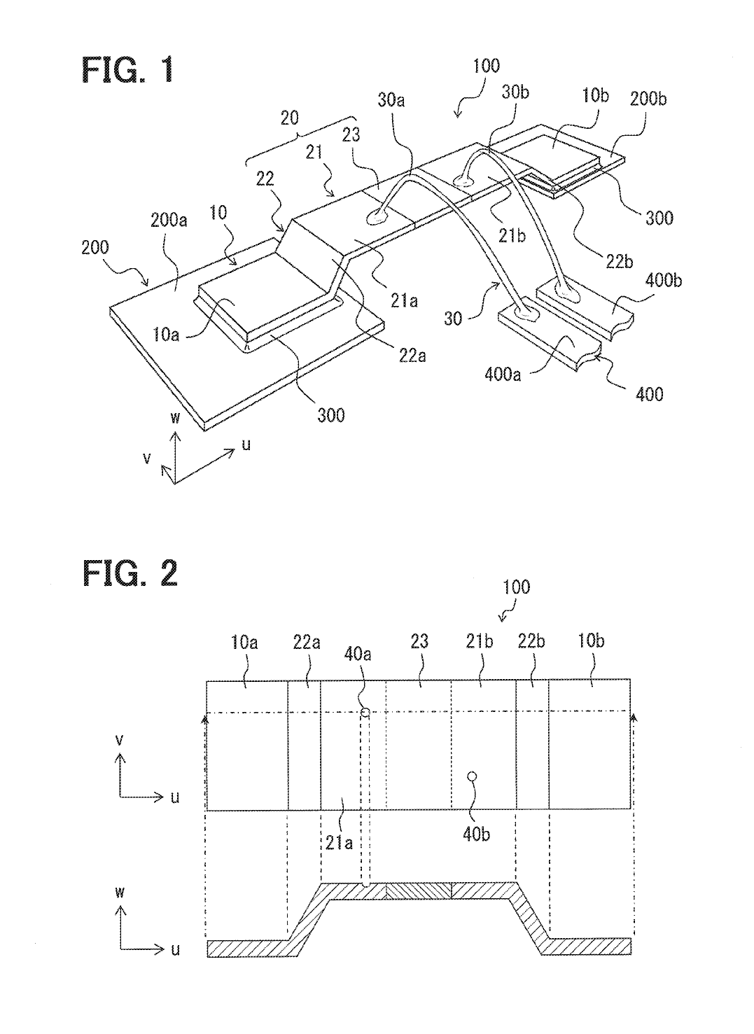

First, a schematic configuration of a shunt resistor according to the present embodiment will be described with reference to FIG. 1 and FIG. 2.

As shown in FIG. 1, the shunt resistor 100 has a plane along the uv-plane, and electrically connects two electrodes 200 arranged along the u-direction. The shunt resistor 100 described herein is connected to a first electrode 200a and a second electrode 200b. The electrode 200 may be, for example, a land or a lead frame formed on a substrate. However, it is not limited to these examples for configuring the electrode 200.

The shunt resistor 100 includes a pair of connection parts 10 and a bridge part 20. The pair of connection parts 10 is respectively connected to the two electrodes 200 through a solder 300 as a conductive adhesive material. The bridge part 20 forms a bridge between both of the connection parts 10. The bridge part 20 has a main portion 21, an intermediary portion 22 and a resistance element 23. A bonding wire 30 for detecting a value of a current flowing through the resistance element 23 is connected to the shunt resistor 100.

As shown in FIG. 1, the connection parts 10 include a first terminal 10a connected to the first electrode 200a, and a second terminal 10b connected to the second electrode 200b. Each of the connection parts 10 has a planner shape along the uv-plane. The surface of the connection part 10 facing the electrode 200 is connected to the electrode 200 through the solder 300.

The main portion 21 of the bridge part 20 includes a first main portion 21a and a second main portion 21b, both of which are in the form of plates along the uv-plane. The resistance element 23 formed along the uv-plane is arranged such that the first main portion 21a and the second main portion 21b are opposite to each other with respect to the resistance element 23. As shown in FIG. 1, the first main portion 21a, the resistance element 23 and the second main portion 21b are bonded together in order along the u-direction, and are integrated into a conductor as a whole. The conductor formed by integrating the first main portion 21a, the resistance element 23 and the second main portion 21b extends in the u-direction, and electrically connects to the first terminal 10a and the second terminal 10b. The main portion 21 and the resistance element 23 are arranged at a position higher than the position of the connection part 10 in the w-direction.

The intermediary portion 22 of the bridge part 20 connects the connection part 10 to the main portion 21 as shown in FIG. 1. The main portion 21 and the connection part 10 are formed integrally through the intermediary portion 22. In particular, the first main portion 21a and the first terminal 10a is connected through a first intermediary portion 221, and the second main portion 21b and the second terminal 10b are connected through a second intermediary portion 22b. When the shunt resistor 100 is viewed from the v-direction in the front view, the bridge part 20 is substantially formed in a trapezoidal shape having an upper base and leg portions. In particular; the plate-like member configured by integrating the main portion 21 and the resistance element 23 is formed as the upper base, and the intermediary portion 22 is formed as the leg portion so that a trapezoidal shape is substantially formed.

The main portion 21 and the intermediary portion 22 of the bridge part 20 are conductive portions made of metal such as copper, and are configured to have the resistivity lower than the resistance element 23. The resistance element 23 is formed by, for example, CnMnSn or CuMnNi as a main component.

The bonding wire 30 is made of known material such as aluminum. The bonding wire 30 is connected to a sense electrode 400 configured to detect the potential level of the bonding wire 30. The bonding wire 30 includes a first wire 30a and a second wire 30b. As shown in FIG. 1, the first wire 30a has one end bonded to the first main portion 21a, and has another end connected to a first sense electrode 400a of the sense electrode 400. The second wire 30b has one end bonded to the second main portion 21b, and has another end connected to a second sense electrode 400b of the sense electrode 400. In other words, the bonding wire 30 according to the present embodiment has one end bonded to the main portion 21 corresponding to the upper base of bridge part 20 substantially forming a trapezoidal shape.

In addition to the above configuration, the shunt resistor 100 includes marks 40a and 40b which are recognizable by imaging as shown in FIG. 2. The marks 40a and 40b according to the present embodiment are dotted holes. The first mark 40a is formed at the first main portion 21a, and the second mark 40b is formed at the second main portion 21b. In other words, the marks 40a and 40b according to the present embodiment are formed on the same surface connected with the bonding wire 30, in particular, on the bridge part 20.

If light is applied obliquely to the w-direction, shadow is generated at the bridge part 20 by the marks 40a and 40b, and the contrast can be emphasized by the shadow. That is, the marks 40a and 40b are recognizable by imaging. In particular, the recognition of the marks 40a and 40b is realized by detecting the contrast difference between the portion formed by the marks 40a and 40b and the portion not formed by the marks 40a and 40b as an edge through the Canny edge detector or the secondary differential method. The cross-sectional shape of the holes as the marks 40a and 40b is arbitrary. However, it is preferable not to form a corner at the bottom as shown in, for example, FIG. 2. In other words, it is preferable that the bottom part of the hole is roundish. This is to prevent erroneous detection of the mark position due to the edge caused by the corner.

With regard to the mark in the present embodiment, the first mark 40a and the second mark 40b are formed in two dots and each of them can be recognized by imaging. An imaging device (not shown) for taking an image of the shunt resistor 100 has a global coordinate system fixed to the imaging device. The respective coordinates of the first mark 40a and the second mark 40b are determined based on the captured image. The imaging device can define a line segment passing through two points of the first mark 40a and the second mark 40b. The line segment which is virtually defined by the first mark 40a and the second mark 40b corresponds to a virtual line segment.

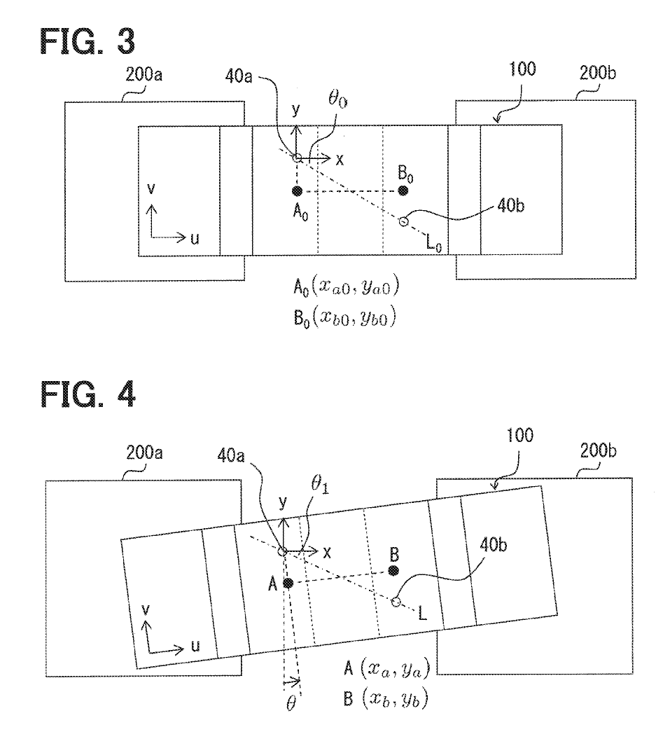

With reference to FIGS. 3 and 4, a mounting method of the shunt resistor 100 according to the present embodiment, in particular, a method of correcting misalignment of the shunt resistor 100 in the rotational direction is described hereinafter.

First of all, a soldering process is carried out. The soldering process refers to a process in which the shunt resistor 100 is electrically connected to the electrode 200 through the solder 300. As shown in FIG. 1, the first terminal 10a of the shunt resistor 100 and the first electrode 200a are welded while the solder 300 is sandwiched by the first terminal 10a and the first electrode 200a. The second terminal 10b of the shunt resistor 100 and the second electrode 200b are welded while the solder 300 is sandwiched between the second terminal 10b and the second electrode 200b. In this case, the u-direction of the shunt resistor 100 is adjusted to coincide with the arrangement direction of the first electrode 200a and the second electrode 200b. However, a rotational shift may occur. FIG. 4 illustrates a rotational shift in a large degree for the simplicity of explanation.

Next, a bonding process is carried out. The bonding process refers to a process for connecting the bonding wire 30 to the shunt resistor 100. The bonding process includes an origin determination step, a virtual line segment detection step, a rotational angle difference determination process, a bonding coordinate determination step and a wire connection step.

First, the situation in which the rotational shift of the shunt resistor 100 does not occur is described with reference to FIG. 3.

The imaging device is arranged such that the x-direction of the global coordinate system fixed to the imaging device coincides with the arrangement direction of the first electrode 200a and the second electrode 200b. That is, in the captured image, the first electrode 200a and the second electrode 200b are aligned along the x-direction.

In the bonding process, the origin determination step is initially carried out. The imaging device captures an image of the welded shunt resistor 100 including the marks 40a and 40b. The imaging device detects an edge caused by the marks 40a and 40b. As described above, the detection of the respective edges of the first mark 40a and the second mark 40b is carried out by detecting the contrast difference between the portion formed by the marks 40a and 40b and the portion where both marks 40a and 40b are not formed as the edge through the Canny edge detector or the secondary differentiation method. The imaging device defines the coordinate at which one of the two marks 40a and 40b is located as the origin in the global coordinate system. In the present embodiment, for example, the first mark 40a is defined as the origin as shown in FIG. 3.

Subsequently, the virtual line segment detection step and the rotational angle difference determination step are executed according to the configuration of a program. However, in a situation where there is no any rotational shift of the shunt resistor 100 such as the one illustrated in FIG. 3, the angular difference obtained by the virtual line segment detection step and the rotational angular difference determination step. Thus, the angle correction for the bonding position is not practically executed. In other words, these two steps are not effective described in the example illustrated in FIG. 3, and thus are described later,

Next, the bonding coordinate determination step is carried out. The imaging device determines a relative fixed coordinate as a position for bonding the bonding wire 30 with respect to the determined origin. In particular, for example, the coordinate, which is separated away from the coordinate of the first mark 40a as the origin with a predetermined distance in the y-direction, is regarded as the bonding coordinate A₀ (xₐ₀, yₐ₀) of the first wire 30a. Additionally, the coordinate, which is separated from the coordinate of the first mark 40a as the origin with a predetermined distance in the x-direction and the y-direction, is regarded as the bonding coordinate B₀ (x_{b0}, y_{b0}) of the second wire 30b. This coordinate is set as an appropriate position in advance, and is determined uniquely under the condition in which there is no rotational shift of the shunt resistor 100. Since this coordinate has the first mark 40a as the origin, the bonding position will not be shifted with respect to the shunt resistor even when the shunt resistor 100 has the translational shift. The translational shift is absorbed in the bonding coordinate determination step. In the following, the bonding coordinates are appended with “0” when there is no rotational shift of the shunt resistor 100. They are generally indicated as (x₀, y₀).

Next, the wiring connection step is carried out. Based on the information of the bonding coordinate determined by the imaging device, the bonder connects the bonding wire 30 to the shunt resistor 100. In particular, the bonder connects the first wire 30a to the bonding coordinate A₀ (xₐ₀, yₐ₀), and connects the second wire 30b to the bonding coordinate B₀ (x_{b0}, y_{b0}). Thus, the bonding process is completed.

The following describes a situation when the rotational shift occurs at the shunt resistor 100 with reference to FIG. 3 and FIG. 4.

The origin determination step is initially carried out. The origin determination step is similar to the situation where there is no shift in the rotational direction. For example, the first mark 40a is defined as the origin as shown in FIG. 4.

Subsequently, the virtual line segment detection step is carried out. The imaging device detects a straight line passing through two different coordinates respectively indicating the first mark 40a and the second mark 40b as the virtual line segment L. The situation where the virtual line segment L is detected refers to a situation where an equation of a straight line of the virtual line segment L in the global coordinate system is determined. FIG. 3 illustrates the virtual line segment Lo in a situation when the shunt resistor 100 does not have a rotational shift.

Next, the rotational angle difference determination step is carried out. The imaging device calculates the angular difference θ1 between the virtual line segment L and the x-direction at the global coordinate system. With regard to the calculation of the angular difference θ1, a general method may be used such as evaluating an inverse tangent of a slope of the straight line of the virtual line signet L. The detailed description is omitted herein. One axis of the two-dimensional orthogonal coordinate system fixed to the imaging device for imaging the shunt resistor corresponds to the x-direction in the present embodiment.

The angular difference θ₀ in a situation when the shunt resistor 100 does not have a rotational shift refers to the angular difference between the virtual line segment Lo and the x-direction as shown in FIG. 3. The angular difference θ₀ is determined uniquely when the formation positions of two respective marks 40a and 40b are decided, and then the angular difference θ₀ is preliminarily stored in the imaging device to be used for correcting the rotational shift.

In other words, the imaging device computes θ₀−θ₁ (=θ) to determine the angular difference θ of the shift of the shunt resistor 100 in the rotational direction. The virtual line segment fixed at the shunt resistor and the predefined straight line respectively correspond to the virtual line segment L and the virtual line segment L₀. The angular difference between the both lines L and L₀ is θ.

Next, the bonding coordinate determination step is carried out. Firstly, the imaging device computes the bonding coordinates in a situation where the rotational shift of the shunt resistor 100 does not occur based on the coordinate of the origin. That is, the imaging device computes the bonding coordinate A₀ (xₐ₀, yₐ₀) prior to the correction of the rotational shift and the bonding coordinate B₀ (x_{b0}, y_{b0}) prior to the correction of the rotational shift. The computation of the coordinates prior to the correction of the rotational shift is similar to the situation where the rotational shift does not occur.

Subsequently, the coordinates A (xₐ, yₐ) and B (x_{b}, y_{b}), which are obtained by rotating the bonding coordinates A₀ and B₀ prior to the correction of the rotational shift with θ around the origin, are determined as the corrected coordinates. As a result, even when the shunt resistor 100 is welded in an unintentionally rotated state, the bonding wire 30 can be bonded at a position the same as the bonding position in a situation where the rotational angle does not occur.

The correction method is not limited to the above described example as long as the correction is made to carryout bonding at the coordinate, which is rotated by the angle difference θaround the origin with respect to the bonding coordinates (x₀, y₀) of the situation when there is no rotational shift of the shunt resistor 100, and the corrected bonding coordinate (x, y) and the bonding coordinate (x₀, y₀) prior to correction satisfy the relationship shown in the Math Equation 1.

$$[ \begin{matrix}x \\ y\end{matrix} ] = [ \begin{matrix}cos θ & - sin θ \\ sin θ & cos θ\end{matrix} ] [ \begin{matrix}{x}_{0} \\ {y}_{0}\end{matrix} ] \qquad [ Math Equation 1 ]$$

Next, the effects of adopting the shunt resistor 100 of the present embodiment will be described.

The shunt resistor 100 includes two marks 40a and 40b, which are detectable by the imaging device. Based on these two points, it is possible to define a linear equation in the global coordinate system. In other words, the shunt resistor 100 includes the marks 40a and 40b, which can define the virtual line segment L. It is possible to calculate the rotational angle difference θ as the rotational shift angle of the shunt resistor 100. With the use of this rotational angle difference θ, it is possible to correct the bonding coordinates of the bonding wire 30.

The marks 40a and 40b according to the present embodiment are formed in the main portion 21 of the bridge part 20 that has the same surface to which the bonding wire 30 is to be bonded. Since the surface to calculate the angular difference θ and the surface at which bonding is carried out coincide with each other in the w-direction, the bonding error due to parallax can be suppressed.

The two marks 40a and 40b are formed to be opposite to each other with respect to the resistance element 23. In particular, the first mark 40a is formed at the first main portion 21a, and the second mark 40b is formed at the second main portion 21b. When puncturing the holes as the marks 40a and 40b, impact or stress applied to the shunt resistor 100 is not unevenly distributed. Therefore, it is possible to suppress deformation of the shunt resistor 100 caused by the mark formation.

### Second Embodiment

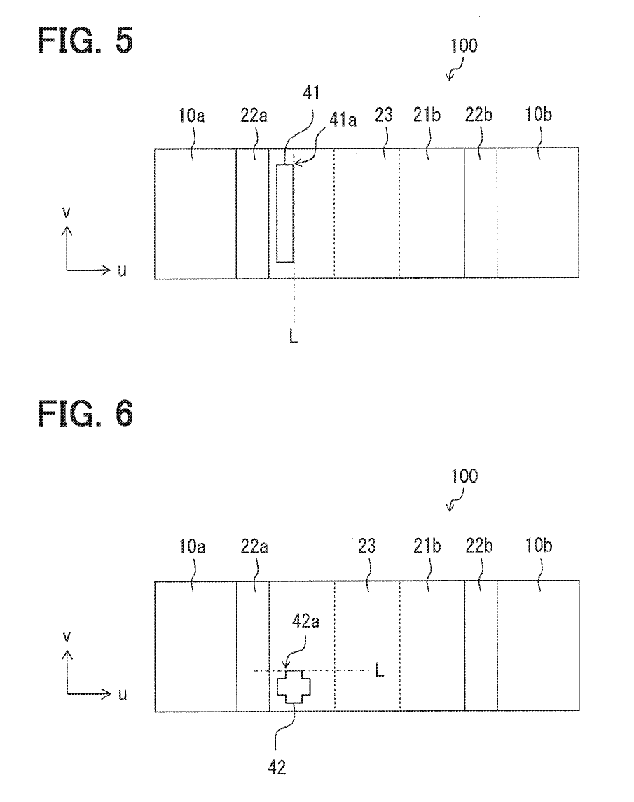

The first embodiment describes an example of using two dotted marks 40a and 40b for defining the virtual line segment L. However, marks may not be in dotted shapes. For example, one strip-shaped mark 41 may be used as shown in FIG. 5. The strip shape is formed by two long sides and two short sides. The long side or short side corresponds to a linear portion.

When the mark 41 is configured in a strip shape, the straight line along, for example, the long side is defined as a virtual line segment L. One of the end points of the long side is defined as the origin 41a. Similarly to the first embodiment, the bonding wire can be connected by correcting the rotational shift of the shunt resistor 100.

The mark may not be limited to a dotted shape as described in the first embodiment and a strip-shape described in the present embodiment. For example, as shown in FIG. 6, the mark 42 may be formed in a cross-shape. The contour of the hole formed in the cross shape includes 12 linear portions. When the mark 42 is configured in a cross-shape, a straight line along an arbitrary side is defined as a virtual line segment L. One of the end points of the side passing through the virtual line segment L is defined as the origin 42a. Similarly to the first embodiment, the bonding wire can be connected by correcting the rotational shift of the shunt resistor 100.

### Other Embodiments

While preferred embodiments of the present disclosure have been described above, the present disclosure is not limited in any way by the embodiments described above, and may be carried out with various modifications without departing from the scope of the subject matter of the present disclosure.

The first embodiment describes that two dotted marks 40a and 40b are opposite to each other with respect to the resistance element 23, and both of the dotted marks are respectively formed at the first main portion 21a and the second main portion 21b. Both of the dotted marks 40a and 40b may be formed at the first main portion 21a, or both of the dotted marks 40a and 40b may be formed at the second main portion 21b.

Each of the embodiments describe an example where the marks 40a, 40b, 41 and 42 are formed at the main portion 21 which is the same as the connection surface of the bonding wire 30. However, they may be formed at the connection part 10. The intermediary portion 22 is sometimes formed to be tilted to the z-direction with respect to the imaging plane of the imaging device. Therefore, it cannot be said that the intermediary portion is preferable to be the formation surface for the marks 40a, 40b, 41 and 42. However, the intermediary portion 22 does not hinder the formation of the marks 40a, 40b, 41 and 42.

Each of the above embodiments describes that the marks 40a, 40b, 41 and 42 are formed as holes. However, it is not necessarily required that the marks 40a, 40b, 41 and 42 are formed as holes. A protrusion may be formed as the mark in the w-direction. The mark may be drawn by printing with laser. An edge side may be formed by applying a resist film to the mark.

The present disclosure has been described with reference to working examples, but the present disclosure should not be limited to these working examples or the configurations. The present disclosure can include various modification examples as well as modifications made within equivalent ranges. Furthermore, various combinations and formations, and other combinations and formations including one or more than one or less than one element may be included in the scope and the spirit of the present disclosure.

1. A shunt resistor having a resistance element with a predetermined resistivity at least at a part, and to which a bonding wire is to be connected, the bonding wire for detecting a value of current flowing between two electrodes bridged through the shunt resistor by detecting a voltage drop at the resistance element, the shunt resistor comprising:
a pair of connection parts to be respectively electrically connected to the two electrodes;
a bridge part having the resistance element, extending from one of the connection parts to the other of the connection parts, and bridging the pair of connection parts; and
a mark configured to define a virtual line segment when a surface of the shunt resistor; which is to be connected with the bonding wire, is imaged from a front view,
wherein the mark is arranged to allow the virtual line segment to be oblique with respect to an extending direction of the bridge part.

2. The shunt resistor according to claim 1,
wherein the mark is provided for correcting a connection position of the bonding wire.

3. The shunt resistor according to claim 1,
wherein the mark is arranged at the surface of the shunt resistor, the surface to which the bonding wire is to be connected.

4. The shunt resistor according to claim 3, wherein:
the bonding wire is bonded with the bridge part; and
the mark is arranged at the bridge part.

5. The shunt resistor according to claim 1, wherein:
the mark is configured as dots, and at least two of the dots are detected when the mark is imaged; and
the virtual line segment is defined by a straight line connecting the at least two dots.

6. The shunt resistor according to claim 5,
wherein the at least two of the dots are arranged at respective positions, which are opposite to each other with respect to the resistance element.

7. The shunt resistor according to claim 1,
wherein the mark includes a linear portion, and the virtual line segment is defined by an edge along the linear portion.

8. The shunt resistor according to claim 7,
wherein the mark is in a strip shape, and the virtual line segment is defined by an edge along the linear portion of the mark in a longitudinal direction.

9. The shunt resistor according to claim 1,
wherein the mark is a hole.

10. A method of mounting the shunt resistor according to claim 1, comprising:
detecting angular difference between the virtual line segment at the shunt resistor and a preliminarily defined straight line; and
correcting a connection position of the bonding wire according to the angular difference.

11. A shunt resistor having a resistance element with a predetermined resistivity at least at a part, and to which a bonding wire is to be connected, the bonding wire for detecting a value of current flowing between two electrodes bridged through the shunt resistor by detecting a voltage drop at the resistance element, the shunt resistor comprising:
a pair of connection parts to be respectively electrically connected to the two electrodes;
a bridge part having the resistance element, extending from one of the connection parts to the other of the connection parts, and bridging the pair of connection parts; and
a mark configured to define a virtual line segment when a surface of the shunt resistor, which is to be connected with the bonding wire, is imaged from a front view,
wherein the mark is at a position separated from the center of the resistance element and is in a direction perpendicular to an extending direction of the bridge part to allow the virtual line segment being parallel to the extending direction of the bridge part.

12. A method of mounting the shunt resistor according to claim 11, comprising:
detecting angular difference between the virtual line segment at the shunt resistor and a preliminarily defined straight line; and
correcting a connection position of the bonding wire according to the angular difference.
